(19) United States
(12) Patent Application Publication
(10) Pub. No.: US 2024/0397622 A1
(43) Pub. Date: Nov. 28, 2024

(54) PRINTED WIRING BOARD AND METHOD FOR MANUFACTURING PRINTED WIRING BOARD

(71) Applicant: IBIDEN CO., LTD., Ogaki (JP)

(72) Inventors: Yoshiki MATSUI, Ogaki (JP); Masamichi KOBAYASHI, Ogaki (JP)

(73) Assignee: IBIDEN CO., LTD., Ogaki (JP)

(21) Appl. No.: 18/670,300

(22) Filed: May 21, 2024

(30) Foreign Application Priority Data
May 22, 2023 (JP) 2023-084210

(51) Int. Cl. H05K 1/11; H05K 1/03; H05K 3/18

(52) U.S. Cl. CPC H05K 1/115; H05K 1/0373; H05K 3/188; H05K 2201/09854

(57) ABSTRACT

A printed wiring board includes an insulating layer, and a conductor layer formed on the insulating layer and having degas holes formed such that the degas holes are penetrating through the conductor layer and exposing portions of the insulating layer. The conductor layer is formed such that each of the degas holes is a polygon shape having at least one inner angle of 100 degrees or more.

### CROSS-REFERENCE TO RELATED APPLICATIONS

The present application is based upon and claims the benefit of priority to Japanese Patent Application No. 2023-084210, filed May 22, 2023, the entire contents of which are incorporated herein by reference.

### BACKGROUND OF THE INVENTION

### Field of the Invention

The present invention relates to a printed wiring board and a method for manufacturing the printed wiring board.

### Description of Background Art

Japanese Patent Application Laid-Open Publication No. 2020-107860 describes a wiring substrate, in which a first pattern including multiple wirings and a second pattern including degas holes are formed on an insulating layer, and a method for manufacturing the wiring substrate. The entire contents of this publication are incorporated herein by reference.

### SUMMARY OF THE INVENTION

According to one aspect of the present invention, a printed wiring board includes an insulating layer, and a conductor layer formed on the insulating layer and having degas holes formed such that the degas holes are penetrating through the conductor layer and exposing portions of the insulating layer. The conductor layer is formed such that each of the degas holes is a polygon shape having at least one inner angle of 100 degrees or more.

According to another aspect of the present invention, a method for manufacturing a printed wiring board includes forming a seed layer on an insulating layer, forming a dry film resist on the seed layer having an opening pattern, forming a metal plating film in the opening pattern of the dry film resist, and removing the dry film resist and the seed layer under the dry film resist such that a conductor layer including the metal plating film and having degas holes is formed on the insulating layer and that the degas holes are penetrating through the conductor layer and exposing portions of the insulating layer. The forming the dry film resist includes removing part of the dry film resist such that the dry film resist has polygon shapes each having at least one inner angle of 100 degrees or more, and the conductor layer is formed such that each of the degas holes is a polygon shape having at least one inner angle of 100 degrees or more.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2A is a schematic diagram illustrating planar shapes of degas holes of a printed wiring board according to an embodiment of the present invention;

FIG. 2B is a schematic diagram illustrating planar shapes of degas holes of a printed wiring board according to an embodiment of the present invention;

FIG. 2C is a schematic diagram illustrating planar shapes of degas holes of a printed wiring board according to an embodiment of the present invention;

FIG. 3A is a diagram for describing a process of a method for manufacturing a printed wiring board according to an embodiment of the present invention;

FIG. 3B is a diagram for describing a process of a method for manufacturing a printed wiring board according to an embodiment of the present invention;

FIG. 3C is a diagram for describing a process of a method for manufacturing a printed wiring board according to an embodiment of the present invention;

FIG. 3D is a diagram for describing a process of a method for manufacturing a printed wiring board according to an embodiment of the present invention; and

FIG. 3E is a diagram for describing a process of a method for manufacturing a printed wiring board according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Structure of Printed Wiring Board

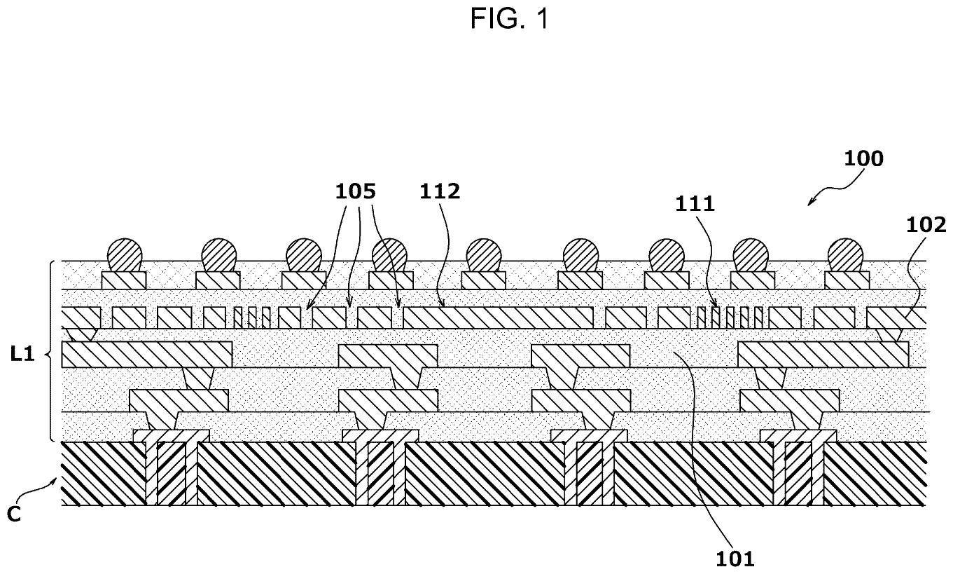

FIG. 1 is a cross-sectional view schematically illustrating a printed wiring board according to an embodiment of the present invention, especially a portion including a power supply layer or GND layer. As illustrated in FIG. 1, a printed wiring board 100 includes an insulating layer 101, multiple wirings 111, a power supply layer or GND layer 112, and multiple degas holes 105, the wirings 111 and the power supply layer or GND layer 112 being formed on the insulating layer 101, and the degas holes 105 being formed in the power supply layer or GND layer 112 and penetrating a conductor layer 102. The insulating layer 101 and the conductor layer 102 are formed in a build-up layer (L1) on a core substrate (C).

The insulating layer 101 may be formed to contain inorganic particles and an insulating resin. The inorganic particles may be an inorganic filler formed of silica, alumina, talc, barium sulfate, titanium oxide, zinc oxide, and the like. The insulating resin may be an epoxy resin, a polyimide resin, or a phenol resin.

The conductor layer 102 is formed on a surface of the insulating layer 101. The conductor layer 102 includes the multiple wirings 111 and the power supply layer or GND layer 112. Thickness and (wiring width)/(wiring spacing) (L/S) of the multiple wirings 111 included in the conductor layer 102 can be appropriately set according to a design of the printed wiring board 100. The multiple wirings 111 included in the conductor layer 102 may be subjected to an anti-rust treatment. The conductor layer 102 is formed of a seed layer (not illustrated) formed of a metal thin film, and a metal plating film (not illustrated) formed on the seed layer. The seed layer may be formed of an electroless copper plating film. The metal plating film may be formed of, for example, an electrolytic copper plating film.

The printed wiring board 100 has the multiple degas holes 105 that penetrate the power supply layer or GND layer 112 included in the conductor layer 102. Since the degas holes 105 penetrate the conductor layer 102 in a lamination direction, the insulating layer 101 is exposed at bottoms of the degas holes 105. Therefore, the degas holes 105 serve as paths through which a gas generated from the insulating layer 101 can move toward an outward direction of the printed wiring board 100. That is, the degas holes 105 have a degassing function that smoothly discharges a gas generated from the insulating layer 101 to outside of the printed wiring board 100.

When the printed wiring board 100 has multiple buildup layers, a gas is generated from each of the insulating layers 101 that form the buildup layers. A gas generated from each insulating layer 101 passes through the degas holes 105 that penetrate the conductor layer 102 formed on each insulating layer 101 and is discharged to the outside of the printed wiring board 100 by passing through the multiple build-up layers.

An embodiment of the present invention is characterized in that a planar shape of each of the degas holes 105 is a polygon with at least one inner angle being 100 degrees or more. Here, the planar shape of each of the degas holes 105 means a shape identified from a flat surface (upper surface) side of the printed wiring board 100. Examples of polygons that can be adopted as the planar shape of each of the degas holes 105 include an approximate quadrilateral (approximate parallelogram), an approximate regular pentagon, an approximate regular hexagon, an approximate regular heptagon, an approximate regular octagon, an approximate regular dodecagon, and the like. At least one inner angle of the polygonal planar shape of each of the degas holes 105 is 100 degrees or more. The inner angle included in the polygonal planar shape of each of the degas holes 105 is an inner angle formed by a first side of the polygonal planar shape of each of the degas holes 105 and a second side adjacent to the first side and is a largest angle.

The polygonal planar shape of each of the degas holes 105 may have multiple inner angles of 100 degrees or more in accordance with the polygonal shape. Further, inner angles other than the inner angles of 100 degrees or more included in the polygonal planar shape of each of the degas holes 105 are not particularly restricted.

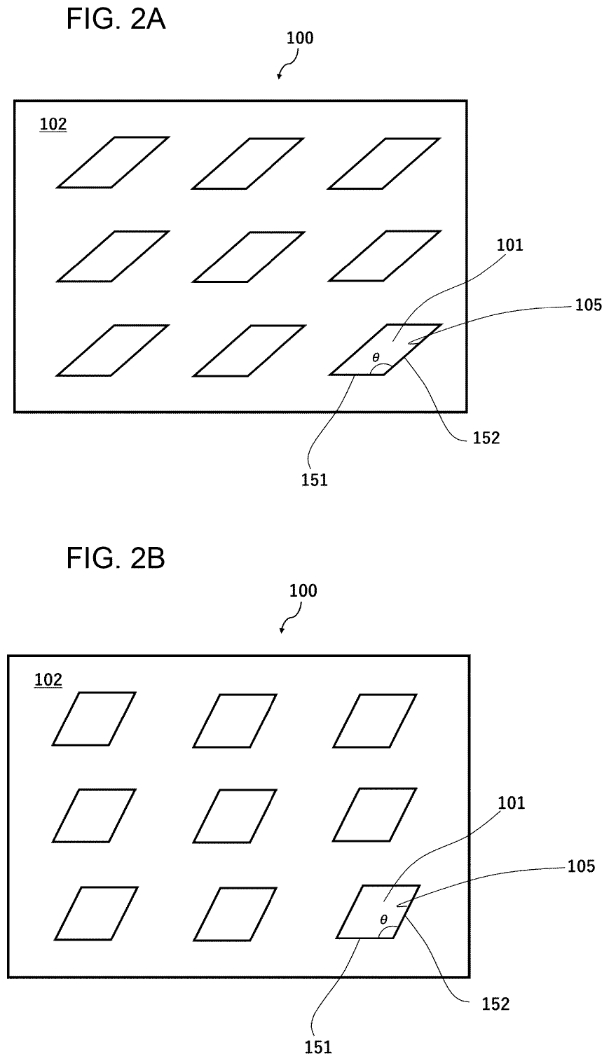

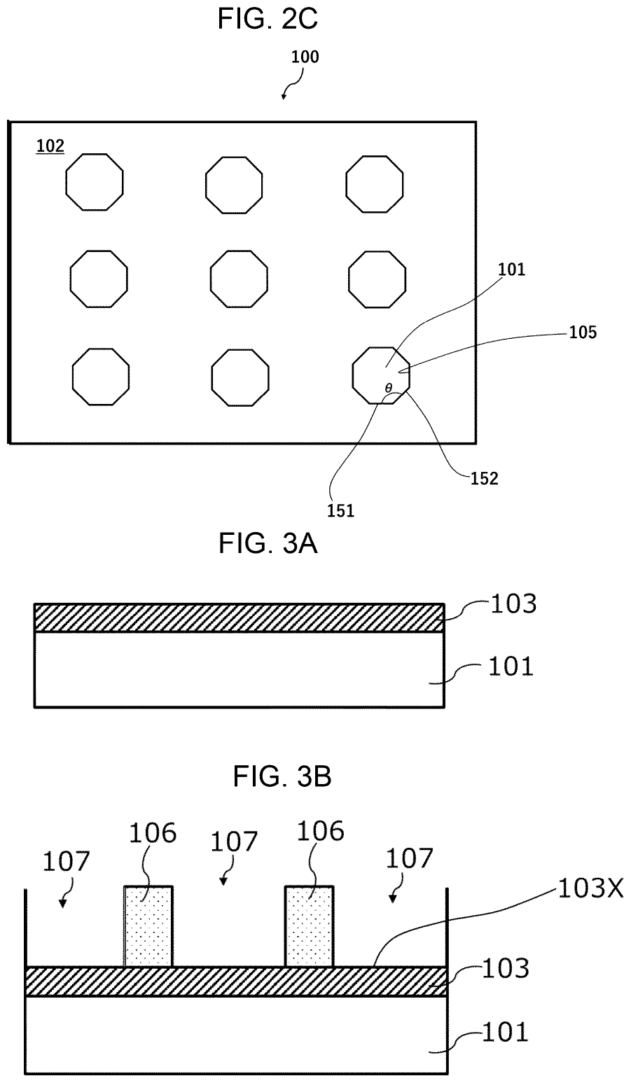

FIG. 2A is a schematic diagram illustrating the planar shapes of the degas holes 105 of the printed wiring board 100. As illustrated in FIG. 2A, the polygonal planar shape of each of the degas holes 105 may be an approximate quadrilateral (approximate parallelogram), and an inner angle (0) formed between a first side 151 of the approximate quadrilateral (approximate parallelogram) and a second side 152 adjacent to the first side 151 may be 135 degrees.

FIG. 2B is a schematic diagram illustrating the planar shapes of the degas holes 105 of the printed wiring board 100. As illustrated in FIG. 2B, the polygonal planar shape of each of the degas holes 105 may be an approximate quadrilateral (approximate parallelogram), and an inner angle (0) formed between a first side 151 of the approximate quadrilateral (approximate parallelogram) and a second side 152 adjacent to the first side 151 may be 120 degrees.

FIG. 2C is a schematic diagram illustrating the planar shapes of the degas holes 105 of the printed wiring board 100. As illustrated in FIG. 2B, the polygonal planar shape of each of the degas holes 105 may be an approximate regular octagon, and an inner angle (0) formed between a first side 151 of the approximate regular octagon and a second side 152 adjacent to the first side 151 may be 135 degrees.

Further, the polygonal planar shape of each of the degas holes 105 may be an approximate regular pentagon, and an inner angle (θ) formed between a first side 151 and a second side 152 adjacent to the first side 151 may be set to 108 degrees. Further, the polygonal planar shape of each of the degas holes 105 may be an approximate regular dodecagon, and an inner angle (θ) formed between a first side 151 and a second side 152 adjacent to the first side 151 may be set to 150 degrees.

In this way, the degas holes 105 are not particularly restricted as long as the degas holes 105 each have a polygonal planar shape with at least one inner angle being 100 degrees or more, and the degas holes 105 may each adopt any polygonal planar shape as long as at least one inner angle of the polygonal planar shape is in that range. The planar shape of each of the degas holes 105 can be appropriately set based on a design of the conductor layer 102.

The planar shapes of the degas holes 105 may be the same across the entire printed wiring board 100 or may be partially different. Multiple degas holes 105 can be provided at predetermined intervals. A pitch between the degas holes 105 may be 5 μm-50 μm.

Further, by setting the degas holes 105 of the printed wiring board 100 to each have a polygonal planar shape with at least one inner angle being 100 degrees or more, there are substantially no remaining peeling film residues of a dry film resist (DFR) 106 used in a process of forming the degas holes 105 each having the predetermined planar shape described above, on corners, bottoms, and wall surfaces inside the degas holes 105.

That is, in the printed wiring board 100, by forming the degas holes 105 each having a predetermined form, occurrence of peeling film residues due to the dry film resist 106 used in the process of forming the degas holes 105 can be prevented.

In the following, a method for manufacturing a printed wiring board having the degas holes in which occurrence of peeling film residues due to the dry film resist is prevented is described.

### Method for Manufacturing Printed Wiring Board

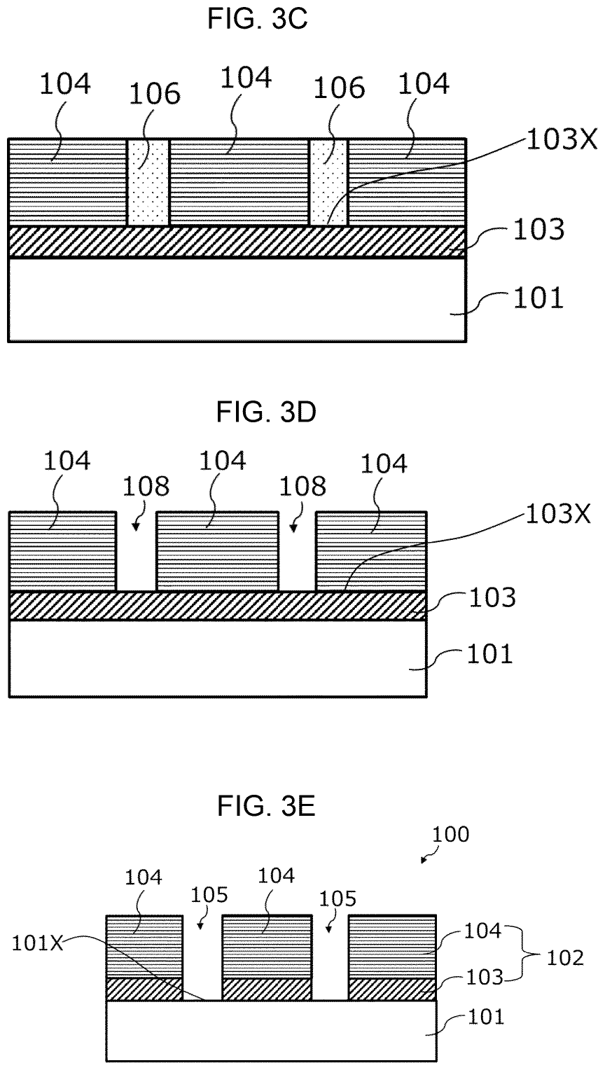

FIGS. 3A-3E are diagrams for describing a method for manufacturing a printed wiring board according to an embodiment of the present invention. In particular, a portion including the power supply layer or GND layer 112 is illustrated. As illustrated in FIG. 3A, a seed layer 103 is formed on the insulating layer 101. The seed layer 103 is formed of an electroless plated film.

As illustrated in FIG. 3B, the dry film resist 106 having multiple portions is formed on the seed layer 103. Positions where the multiple portions of the dry film resist 106 are formed will become positions where the degas holes 105 are formed in a subsequent manufacturing process of the printed wiring board.

Forming the dry film resist 106 having the multiple portions on the seed layer 103 is performed, for example, by applying a dry film onto a seed layer upper surface (103X) using a laminate roll or the like, and then performing exposure and development.

Here, the degas holes 105 are set to each have a polygonal planar shape with at least one inner angle being 100 degrees or more. Therefore, by removing a part of the formed dry film resist 106, an opening pattern 107 for forming the degas holes 105 that each have a polygonal planar shape with at least one inner angle being 100 degrees or more is formed.

As illustrated in FIG. 3C, a metal plating film 104 is formed in the opening pattern 107, for example, by electrolytic copper plating.

As illustrated in FIG. 3D, the remaining dry film resist 106 is removed from the seed layer 103 using, for example, sodium hydroxide. A planar shape of the remaining dry film resist 106 formed by removing a portion of the dry film resist 106 is a polygon protruding outward from the insulating layer 101. Therefore, when the remaining dry film resist 106 is peeled off from the seed layer 103, an appropriate amount of stress strain can be generated at the corners.

That is, in order to form the degas holes 105 each having a polygonal planar shape with at least one inner angle being 100 degrees or more, by causing the planar shape of the remaining dry film resist 106 to protrude outward and making the multiple portions thereof to have angled shapes, and thereby generating an appropriate amount of stress strain at the angled portions of the dry film resist 106, peelability can be significantly improved when the remaining dry film resist 106 is peeled off from the seed layer 103.

That is, in the printed wiring board 100, by setting the degas holes 105 to each have a predetermined planar shape and making the multiple portions of the remaining dry film resist 106 to have angled planar shapes, an appropriate amount of stress strain can be generated at the corners.

In this way, in the printed wiring board 100, the degas holes 105 each have a polygonal planar shape with at least one inner angle being 100 degrees or more. Therefore, in the printed wiring board 100, in a manufacturing process of the printed wiring board 100, an appropriate amount of stress strain can be sufficiently generated at corners of a required remaining portion when the dry film resist 106 is peeled off.

As a result, the remaining dry film resist 106 can be peeled off from the seed layer 103 extremely easily and can be completely removed. Further, no peeling film residues due to the remaining dry film resist 106 are generated inside the degas holes 105 that penetrate the conductor layer 102. By removing the remaining dry film resist 106 from the seed layer 103, the seed layer upper surface (103X) of the seed layer 103 that is formed under the dry film resist 106 is exposed.

As illustrated in FIG. 3E, the seed layer 103 exposed from the metal plating film 104 is etched. As a result, the insulating layer 101 formed under the seed layer 103 is exposed.

In this way, the multiple degas holes 105 penetrating the conductor layer 102 are formed on an insulating layer upper surface (101X). Further, substantially no peeling film residues of the dry film resist 106 are generated inside the degas holes 105.

### EXAMPLES

In the following, an embodiment of the present invention is specifically described based on examples. However, the present invention is not limited to these examples.

### Example 1

A printed wiring board according to an embodiment of the present invention was manufactured as follows. An insulating layer with a seed layer formed of an electroless plating film was prepared, and a dry film resist was formed on the seed layer. After a portion of the dry film resist was removed, a metal plating film was formed in an opening pattern formed by the dry film resist adjacent to a seed layer upper surface. After that, the remaining dry film resist was peeled off from the seed layer, and then, the seed layer on the insulating layer was etched. By etching the seed layer on the insulating layer, degas holes that penetrate the conductor layer are formed on the insulating layer.

In Example 1, the planar shape of each of the degas holes of the printed wiring board was a parallelogram, and an inner angle (θ) formed between a first side of the parallelogram and a second side adjacent to the first side was 135 degrees.

Here, the angle (θ) refers to an inner angle formed by a first side of the polygonal planar shape of each of the degas holes of the printed wiring board and a second side adjacent to the first side and refers to a largest angle.

Areas of the degas holes were set to be the same as calculated areas(S) of circular degas holes with diameters (D) of Φ80, Φ90, Φ100, 150, and Φ200, and five types of degas holes with parallelogram planar shapes corresponding to Φ80, Φ90, Φ100, Φ150, and Φ200 were formed. For the two cases where the planar shape of each of the degas holes was a parallelogram and where the planar shape was circular, visual observation was performed and an amount of dry film resist residues remaining in the printed wiring board after peeling off the dry film resist was measured.

For the dry film resist, a commercially available dry film resist was used. The dry film resist had a thickness of 25 μm and a development time of 23 seconds. The amount of dry film resist residues was measured using a microscope.

A dry film resist residue degas hole rate was calculated based on the measured amount of dry film resist residues in the case where the planar shape of each of the degas holes was a parallelogram, and the measured amount of dry film resist residues in the case where the planar shape of each of the degas holes was circular. Table 1 shows the calculation results of the dry film resist residue degas hole rate (%).

### Examples 2 and 3

Printed wiring boards were each manufactured in the same way as in Example 1, except that the planar shape of each of the degas holes was changed to a different shape. Specifically, in Example 2, the planar shape of each of the degas holes was a parallelogram, and an inner angle (θ) formed between a first side of the parallelogram and a second side adjacent to the first side was 120 degrees.

Further, in Example 3, the planar shape of each of the degas holes was a regular octagon, and an inner angle (θ) formed between a first side of the regular octagon and a second side adjacent to the first side was 135 degrees. Table 1 shows the calculation results of the dry film resist residue degas hole rate (%).

### Comparative Examples 1-3

Printed wiring boards were each manufactured in the same way as in Example 1, except that the planar shape of each of the degas holes in each of the printed wiring boards was changed to a different shape. Specifically, in Comparative Example 1, the planar shape of each of the degas holes was circular. In Comparative Example 2, the planar shape of each of the degas holes was an isosceles triangle. In Comparative Example 3, the planar shape of each of the degas holes was a regular quadrilateral (square), and an inner angle (θ) formed between a first side of the regular quadrilateral (square) and a second side adjacent to the first side was 90 degrees. Table 1 shows the calculation results of the dry film resist residue degas hole rates (%) of the printed wiring boards manufactured in Comparative Examples 1-3.

TABLE 1

| | | Inner angle | | | |
|---|---|---|---|---|---|
| | | (θ) formed | | | DFR |
| | | by adjacent | Degas hole | Degas | residue |
| | Degas | sides of | corresponding | hole | degas |
| Example | hole | degas hole | diameter (D) | area (S) | hole |
| number | shape | (degree) | (μm) | (μm²) | rate (%) |
| Example 1 | Parallelogram | 135 | Φ200 | 31.4 × 10³ | 0.00 |
| | | | Φ150 | 17.7 × 10³ | 0.00 |
| | | | Φ100 | 7.85 × 10³ | 0.03 |
| | | | Φ90 | 6.36 × 10³ | 0.12 |
| | | | Φ80 | 5.02 × 10³ | 0.60 |
| Example 2 | Parallelogram | 120 | Φ200 | 31.4 × 10³ | 0.00 |
| | | | Φ150 | 17.7 × 10³ | 0.01 |
| | | | Φ100 | 7.85 × 10³ | 0.02 |
| | | | Φ90 | 6.36 × 10³ | 0.15 |
| | | | Φ80 | 5.02 × 10³ | 0.18 |
| Example 3 | Regular | 135 | Φ200 | 31.4 × 10³ | 0.00 |
| | octagon | | Φ150 | 17.7 × 10³ | 0.00 |
| | | | Φ100 | 7.85 × 10³ | 0.06 |
| | | | Φ90 | 6.36 × 10³ | 008 |
| | | | Φ80 | 5.02 × 10³ | 0.11 |
| Comparative | Circle | — | Φ200 | 31.4 × 10³ | 0.00 |
| Example 1 | | | Φ150 | 17.7 × 10³ | 0.09 |
| | | | Φ100 | 7.85 × 10³ | 0.39 |
| | | | Φ90 | 6.36 × 10³ | 0.74 |
| | | | Φ80 | 5.02 × 10³ | 17.44 |
| Comparative | Isosceles | 60 | Φ200 | 31.4 × 10³ | 0.00 |
| Example 2 | triangle | | Φ150 | 17.7 × 10³ | 0.00 |
| | | | Φ100 | 7.85 × 10³ | 5.10 |
| | | | Φ90 | 6.36 × 10³ | 10.08 |
| | | | Φ80 | 5.02 × 10³ | 12.71 |
| Comparative | Regular | 90 | Φ200 | 31.4 × 10³ | 0.00 |
| Example 3 | quadrilateral | | Φ150 | 17.7 × 10³ | 0.22 |
| | | | Φ100 | 7.85 × 10³ | 0.77 |
| | | | Φ90 | 6.36 × 10³ | 2.38 |
| | | | Φ80 | 5.02 × 10³ | 12.50 |

As is clear from Table 1, in the printed wiring board, by making the degas holes of the printed wiring board to each have a polygonal planar shape with at least one inner angle being 100 degrees or more, the dry film resist can be easily peeled off and the dry film resist residue degas hole rate can be significantly reduced.

The above description is based on the illustrated embodiment. However, the printed wiring board according to an embodiment of the present invention is not limited to the above-described embodiment and can be appropriately modified within the scope of the claims. A printed wiring board according to an embodiment of the present invention can be applied to formation of build-up layers, and miniaturization and densification of wiring patterns.

Japanese Patent Application Laid-Open Publication No. 2020-107860 describes a wiring substrate, in which a first pattern including multiple wirings and a second pattern including degas holes are formed on an insulating layer, and a method for manufacturing the wiring substrate. However, planar shapes of the degas holes of the wiring substrate described in Japanese Patent Application Laid-Open Publication No. 2020-107860 are circular. Therefore, it is difficult to peel off a dry film resist used for forming the degas holes of the wiring substrate from the wiring substrate. As a result, there is a concern that the dry film resist after being used to form the degas holes may not be sufficiently peeled off from the wiring substrate and a portion of the dry film resist may remain on the wiring substrate.

A printed wiring board according to an embodiment of the present invention has degas holes formed using a method that prevents residues of a dry film resist from remaining inside the degas holes.

A printed wiring board according to an embodiment of the present invention includes an insulating layer, a conductor layer formed on the insulating layer, and multiple degas holes that penetrate the conductor layer and expose the insulating layer. A planar shape of each of the degas holes is a polygon with at least one inner angle being 100 degrees or more.

A method for manufacturing a printed wiring board according to an embodiment of the present invention includes forming a seed layer on an insulating layer, forming a dry film resist on the seed layer, forming an opening pattern by removing a portion of the dry film resist, forming a metal plating film in the opening pattern, and removing the remaining dry film resist and the seed layer thereunder. In the forming of the opening pattern, the portion of the dry film resist is removed such that a planar shape of the remaining dry film resist is a polygon with at least one inner angle being 100 degrees or more.

According to an embodiment of the present invention, a printed wiring board can be provided in which degas holes are formed using a method that prevents residues of a dry film resist from remaining inside the degas holes.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
an insulating layer; and
a conductor layer formed on the insulating layer and having a plurality of degas holes formed such that the degas holes are penetrating through the conductor layer and exposing a plurality of portions of the insulating layer,
wherein the conductor layer is formed such that each of the degas holes is a polygon shape having at least one inner angle of 100 degrees or more.

2. The printed wiring board according to claim 1, wherein the conductor layer is formed such that the polygon shape of each of the degas holes is an approximate parallelogram.

3. The printed wiring board according to claim 1, wherein the conductor layer is formed such that the polygon shape of each of the degas holes is an approximate regular octagon.

4. The printed wiring board according to claim 1, wherein the conductor layer includes a plurality of wirings and at least one of a power layer and a ground layer.

5. The printed wiring board according to claim 1, wherein the conductor layer comprises a metal plating film.

6. The printed wiring board according to claim 4, wherein the conductor layer comprises a metal plating film.

7. The printed wiring board according to claim 1, wherein the insulating layer comprises resin.

8. The printed wiring board according to claim 1, wherein the insulating layer comprises resin and inorganic particles.

9. The printed wiring board according to claim 1, wherein the conductor layer is formed such that the plurality of degas holes is formed at a pitch in a range of 5 μm to 50 μm.

10. The printed wiring board according to claim 1, further comprising:
a core substrate such that the insulating layer is formed on the core substrate.

11. A method for manufacturing a printed wiring board, comprising:
forming a seed layer on an insulating layer;
forming a dry film resist on the seed layer having an opening pattern;
forming a metal plating film in the opening pattern of the dry film resist; and
removing the dry film resist and the seed layer under the dry film resist such that a conductor layer comprising the metal plating film and having a plurality of degas holes is formed on the insulating layer and that the degas holes are penetrating through the conductor layer and exposing a plurality of portions of the insulating layer,
wherein the forming the dry film resist includes removing part of the dry film resist such that the dry film resist has a plurality of polygon shapes each having at least one inner angle of 100 degrees or more, and the conductor layer is formed such that each of the degas holes is a polygon shape having at least one inner angle of 100 degrees or more.

12. The method for manufacturing a printed wiring board according to claim 11, wherein the conductor layer is formed such that the polygon shape of each of the degas holes is an approximate parallelogram.

13. The method for manufacturing a printed wiring board according to claim 11, wherein the conductor layer is formed such that the polygon shape of each of the degas holes is an approximate regular octagon.

14. The method for manufacturing a printed wiring board according to claim 11, wherein the conductor layer is formed such that the conductor layer includes a plurality of wirings and at least one of a power layer and a ground layer.

15. The method for manufacturing a printed wiring board according to claim 11, wherein the insulating layer comprises resin.

16. The method for manufacturing a printed wiring board according to claim 11, wherein the insulating layer comprises resin and inorganic particles.

17. The method for manufacturing a printed wiring board according to claim 11, wherein the conductor layer is formed such that the plurality of degas holes is formed at a pitch in a range of 5 μm to 50 μm.

18. The method for manufacturing a printed wiring board according to claim 11, further comprising:
forming the insulating layer on a core substrate.

19. The method for manufacturing a printed wiring board according to claim 14, wherein the insulating layer comprises resin.

20. The method for manufacturing a printed wiring board according to claim 14, wherein the insulating layer comprises resin and inorganic particles.
